(19) United States
(12) Patent Application Publication
(10) Pub. No.: US 2020/0035577 A1
(43) Pub. Date: Jan. 30, 2020

(54) PACKAGED INTEGRATED CIRCUIT

(71) Applicant: Texas Instruments Incorporated, Dallas, TX (US)

(72) Inventors: JAMES RICHARD HUCKABEE, SHERMAN, TX (US); ABRAM MARC CASTRO, CARROLITON, TX (US)

(21) Appl. No.: 16/046,849

(22) Filed: Jul. 26, 2018

(51) Int. Cl. H01L 23/31; H01L 23/00; H01L 23/495; H01L 21/48; H01L 21/56; H01L 21/78; H01L 21/683

(52) U.S. Cl. CPC H01L 23/3121; H01L 2224/04042; H01L 24/16; H01L 23/49541; H01L 24/48; H01L 21/4821; H01L 24/81; H01L 21/565; H01L 21/568; H01L 24/85; H01L 21/561; H01L 21/78; H01L 24/97; H01L 21/6836; H01L 2224/0401; H01L 2224/16245; H01L 2224/48247; H01L 2224/81005; H01L 2224/85005; H01L 2224/48106; H01L 2224/48091; H01L 2924/14; H01L 24/05

(57) ABSTRACT

Described examples include, an integrated circuit package having a die with a surface and at least two bond pads in the first surface. The integrated circuit package also includes at least two leads having a first portion and a second portion, the die coupled to the first portion and the at least two bond pads having a conductive connection the leads, the first portion of the at least two leads having a first width greater than a second width of the second portion. The integrated circuit package also including an encapsulation covering the die and the first portion of the at least two leads, the second portion of the at least two leads extending outside of the encapsulation such that a surface of the second portion is parallel with a surface of the encapsulation and the second portion extends beyond the encapsulation less than a thickness of the encapsulation.

### TECHNICAL FIELD

This application relates generally to integrated circuit packaging, and, in particular to plastic encapsulation integrated circuit packaging.

### BACKGROUND

As electronic devices become more powerful while occupying smaller form factors, the need for compact, inexpensive integrated circuit packages increases. In addition, many of these integrated circuits are used in portable applications such as cell phones, smart watches and portable computers. These devices require impact resistance as well as compact dimensions. Quad-flat-no lead (QFN) packages have become popular for these applications. However, QFN packaging uses costly etched conductor frames and it usually requires heat removal mechanisms. Also, as the name suggests, QFN packages have no leads. In some applications leads are desirable.

### SUMMARY

In accordance with an example, an integrated circuit package includes a die having a first surface, a second surface opposing the first surface and having at least two bond pads in the first surface. The integrated circuit package also includes at least two leads having a first portion and a second portion. The die couples to the first portion and the at least two bond pads have a conductive connection to at least one of the two leads, the first portion of the at least two leads having a first width greater than a second width of the second portion. The integrated circuit package also includes an encapsulation covering the die and the first portion of the at least two leads, the second portion of the at least two leads extending outside of the encapsulation such that a surface of the second portion is in a plane parallel with a surface of the encapsulation and the second portion extends beyond the encapsulation to a length less than a thickness of the encapsulation.

### BRIEF DESCRIPTION OF THE DRAWINGS

FIGS. 1A-1C are diagrams of an example packaged integrated circuit.

FIGS. 2A-2K are diagrams showing an example method.

FIG. 3 shows another example packaged integrated circuit.

FIG. 4 shows another example packaged integrated circuit.

FIG. 5 shows an example of mounting a packaged integrated circuit in an example socket.

FIG. 6 shows another example method of mounting a packaged integrated circuit in another example socket.

FIGS. 7A and 7B are diagrams of another example packaged integrated circuit.

FIG. 8 shows an example method for forming a packaged integrated circuit.

### DETAILED DESCRIPTION

Corresponding numerals and symbols in the different figures generally refer to corresponding parts unless otherwise indicated. The figures are not necessarily drawn to scale.

The term “coupled” may include connections made with intervening elements, and additional elements and various connections may exist between any elements that are “coupled.”

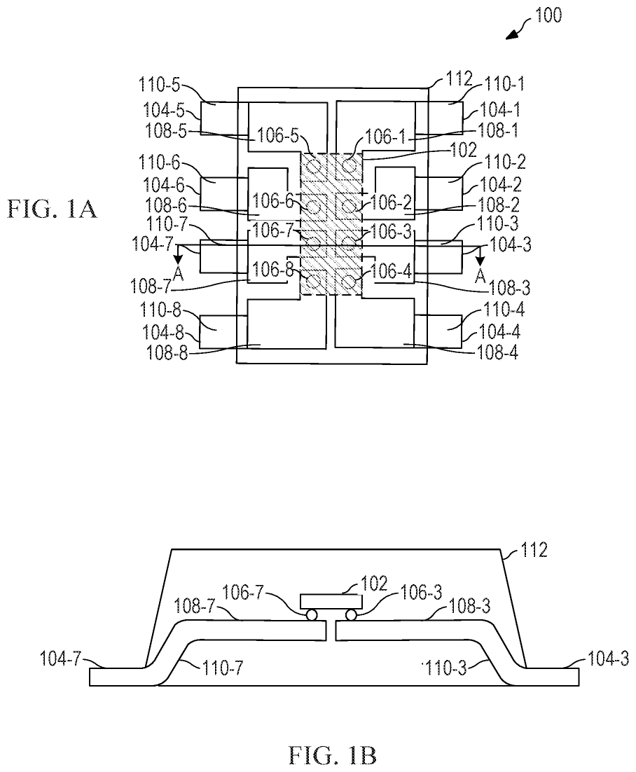

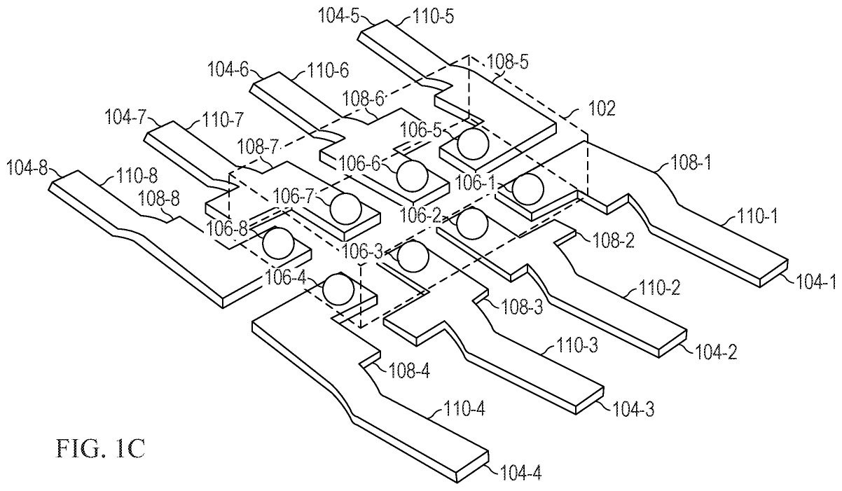

FIG. 1A is a top view diagram of an example packaged integrated circuit 100. As used herein, terms such as “top,” “bottom” and “side” are used solely as relative positional references in the orientation of the figure under discussion. In this example, die or integrated circuit 102 is connected to leads 104-1 through 104-8 by ball bonds 106-1 through 106-8, respectively. Leads 104-1 through 104-8 include first portions 108-1 through 108-8, respectively, and second portions 110-1 through 110-8, respectively. In this example, leads 104-1 through 104-8 are formed of aluminum, copper, alloys thereof or other conductive materials. Also, in this example, first portions 108-1 through 108-8 are separated from each other by a spacing of approximately 0.4 mm or less. Encapsulant 112 encapsulates integrated circuit 102, the first portions 108-1 through 108-8 of leads 104-1 through 104-8 and ball bonds 106-1 through 106-8. In this example, second portions 110-1 through 110-4 and second portions 110-5 through 110-8 extend beyond encapsulant 112 on two opposing sides of encapsulant 112. In this example, encapsulant 112 is formed of injection molded plastic.

FIG. 1B is a side view of example packaged integrated circuit 100 along cut line AA. Ball bond 106-3 connects lead 104-3 to integrated circuit 102 via bond pads on the bottom surface of integrated circuit 102 (not shown). In this example, the bottom surface is the active surface of integrated circuit 102. The active surface of an integrated circuit is the surface in which the devices such as transistors and diodes are formed, and on which most of the interconnections between those devices are formed. In this example, first portions 108-1 through 108-8 are extended above second portions 110-1 through 110-8. In addition, first portions 108-1 through 108-8 are within encapsulant 112. On the other hand, second portions 110-1 through 110-8 extend from first portions 108-1 through 108-8, respectively, such that a portion of a surface of second portions 110-1 through 110-8 is substantially coplanar with a surface of encapsulant 112 and is thus exposed to allow surface bonding of the exposed portions of second portions 110-1 through 110-8 to a circuit board, to contacts within a socket or to another type of electrical connection. In addition, in this example, the exposed surface of second portions 110-1 through 110-8 extends from within the vertical sides of encapsulant 112 to the end of leads 104-1 through 104-8, respectively, thus providing additional bonding area to the surface of second portions 110-1 through 110-8. In this example, encapsulant 112 has a trapezoidal side profile, but encapsulant 112 may be any suitable configuration.

FIG. 1C is a perspective view of leads 104-1 through 104-8, ball bonds 106-1 through 106-8 and integrated circuit 102, which is shown in outline for clarity. In addition, encapsulant 112 is omitted in FIG. 1C for clarity.

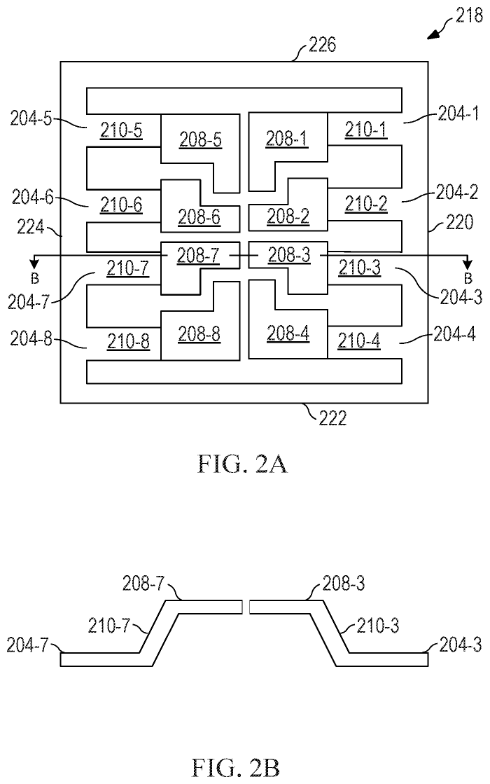

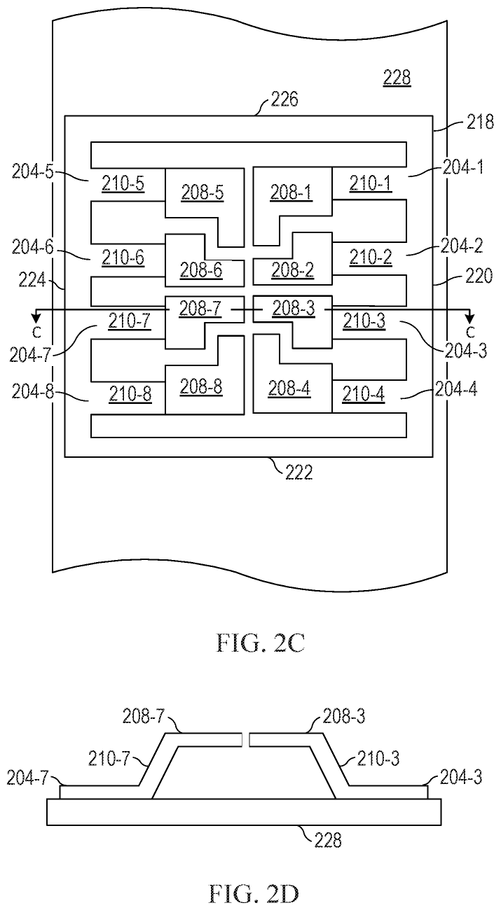

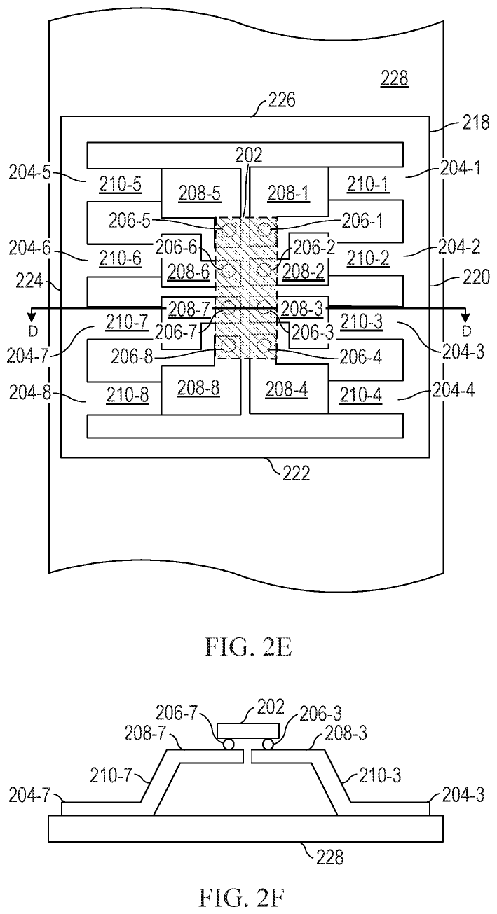

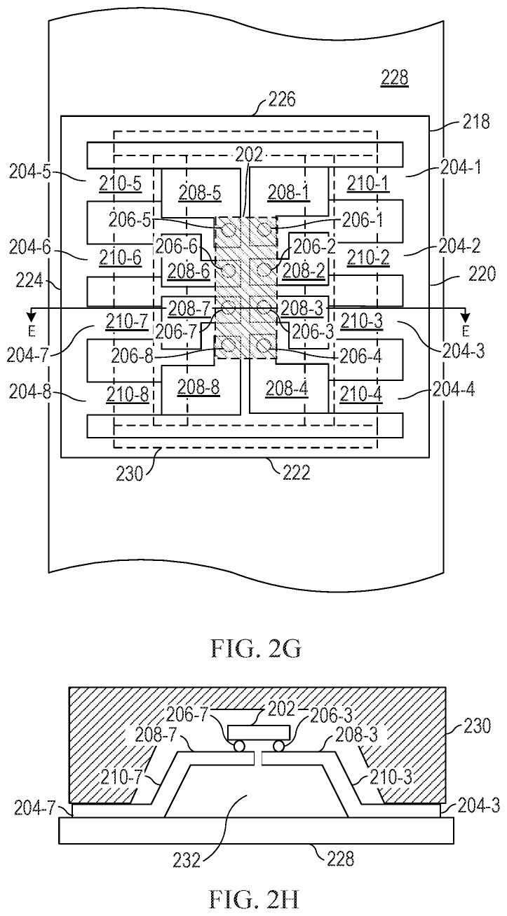

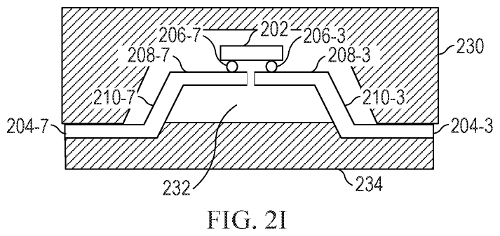

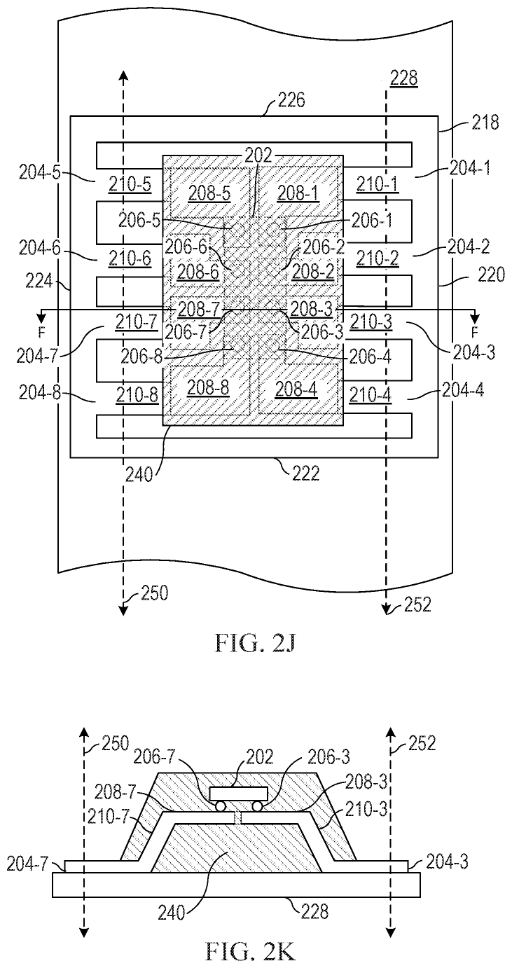

FIGS. 2A-2K show an example method. FIG. 2A is a top view of lead frame 218. Numbers in FIGS. 2A-2K with numbers corresponding to FIGS. 1A-1C perform similar functions. For example, a die or integrated circuit 202, leads 204-1 through 204-8, ball bonds 206-1 through 206-8, first portions 208-1 through 208-8 and second portions 210-1 through 210-8 correspond to integrated circuit 102, leads 104-1 through 104-8, ball bonds 106-1 through 106-8, first portions 108-1 through 108-8 and second portions 110-1 through 110-8 of FIGS. 1A-1C.

FIG. 2A is a top view of a lead frame 218. In an example, lead frame 218 is formed by stamping a sheet of aluminum, copper, alloys thereof or other conductive materials. Leads 204-1 through 204-4 connect to rail 220 in lead frame 218 and leads 204-5 through 204-8 connect to rail 224 in lead frame 218. Rails 222 and 226 connect rails 220 and 224. Lead frame 218 is a single frame in FIG. 2A. However, in practice, lead frame 218 would be part of a lead frame strip extending from rails 222 and 226 or an array of lead frames, so that multiple integrated circuits are encapsulated at one time or in a series. FIG. 2B is a side view along cut line BB of FIG. 2A. During stamping, first portions 208-1 through 208-8 are raised relative to rails 220, 222, 224 and 226 by bending second portions 210-1 through 210-8, respectively, in this example. FIG. 2B more clearly shows the relative position of first portions 208-1 through 208-8.

FIG. 2C shows a top view of lead frame 218 mounted to tape 228. Tape 228 is a pressure sensitive adhesive (PSA) tape. Lead frame 218 is mounted by pressing lead frame 218 onto tape 228. FIG. 2D is a side view along cut line CC showing lead frame 218 mounted to tape 228.

FIG. 2E shows a top view of lead frame 218 with integrated circuit 202 connected to first portions 208-1 through 208-8 by ball bonds 206-1 through 206-8, respectively. In this example, ball bonds 206-1 through 206-8 are solder and mount to bond pads (not shown) on integrated circuit 202 by pressure. The combined integrated circuit 202 with ball bonds 206-1 through 206-8 mounts to first portions 208-1 through 208-8 by pressing the combined integrated circuit 202 with ball bonds 206-1 through 206-8 onto first portions 208-1 through 208-8. FIG. 2F is a side view along cut line DD showing integrated circuit 202 mounted onto leads 204-3 and 204-7 via ball bonds 206-3 and 206-7, respectively.

FIG. 2G shows a top view of mold 230 shown in outline. Mold 230 along with tape 228 enclose all of first portions 208-1 through 208-8, ball bonds 206-1 through 206-8 and integrated circuit 202. FIG. 2H shows a side view of mold 230 along cut line EE showing more clearly the cavity 232 encompassing first portions 208-1 through 208-8, ball bonds 206-1 through 206-8 and integrated circuit 202. In this example, cavity 232 has a trapezoidal shape. However, cavity 232 may have other shapes (for example, rectangular shaped with vertical sides) depending on design choices. Second portions 210-1 through 210-8 are partially within the cavity 232 and partially outside of cavity 232. In addition, a part of second portions within cavity 232 is in contact with tape 228. Encapsulant will not cover the part of second sections 210-1 through 210-8 that is in contact with tape 228.

FIG. 2I shows a side view of mold 230 in another example. In this example, bottom mold 234 replaces tape 228 to form cavity 232. Using bottom mold 234 allows for selection of the point at which first portions 210-1 through 210-8 emerge from encapsulant 240 (FIG. 2J) by selecting the configuration of mold 230 and mold 234.

FIG. 2J shows a top view of encapsulant 240. In an example, plastic molding compound fills cavity 232 to form encapsulant 240. First portions 208-1 through 208-8, ball bonds 206-1 through 206-8 and integrated circuit 202 are within encapsulant 240. Of note, in this example, where first portions 208-1 through 208-8 meets second portions 210-1 through 210-8 is within encapsulant 240. Thus, at least part of all edges of first portions 208-1 through 208-8 are within encapsulant 240. This feature helps to lock first portions 208-1 through 208-8 within encapsulant 240 and limit any loosening of leads 204-1 through 204-8 from within the encapsulant 240. FIG. 2J shows a side view of encapsulant 240 covering first portions 208-1 through 208-8, ball bonds 206-1 through 206-8 and integrated circuit 202.

After formation of encapsulant 240, tape 228 is removed and leads 204-1 through 204-8 are cut along lines 250 and 252, for example. These steps release leads 204-1 through 204-8 from lead frame 218. Thus, the method illustrated in FIGS. 2A-2J forms a packaged integrated circuit like that shown in FIGS. 1A and 1B.

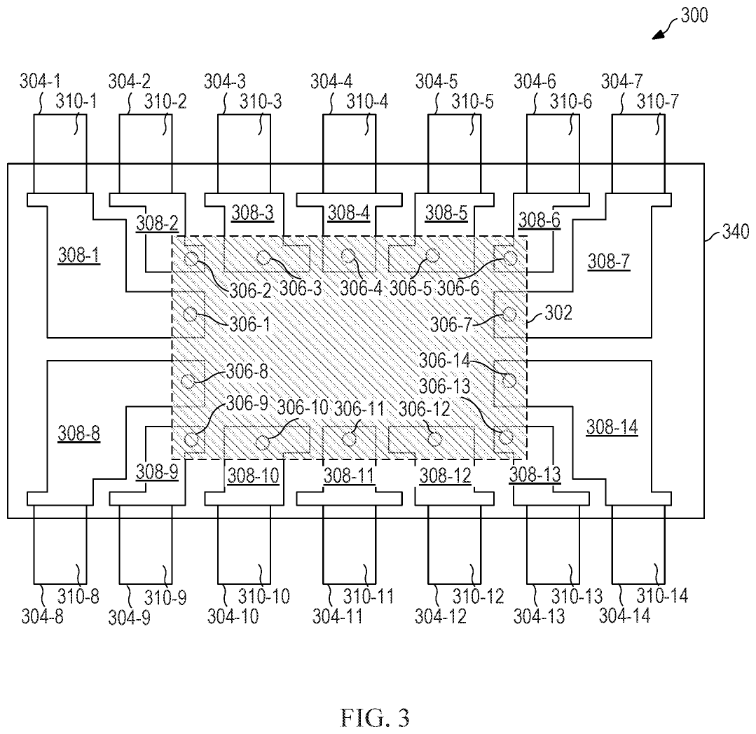

FIG. 3 shows another example packaged integrated circuit 300 having fourteen leads. Integrated circuit 302 mounts to first portions 308-1 through 308-14, respectively, of leads 304-1 through 340-14, respectively via ball bonds 306-1 through 306-14 through bond pads (not shown) on integrated circuit 302. Second portions 310-1 through 310-14 extend from first portions 308-1 through 308-14 to outside of encapsulant 340. Thus, the example of FIG. 3 provides fourteen connections to integrated circuit 302. In an example, the method of FIGS. 2A-2K forms packaged integrated circuit 300.

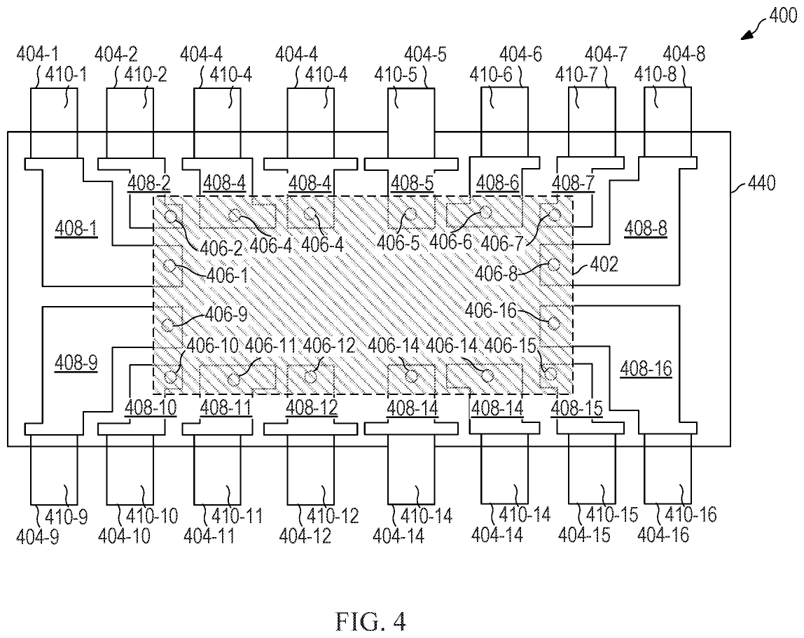

FIG. 4 shows another example packaged integrated circuit 400 having sixteen leads. Integrated circuit 402 mounts to first portions 408-1 through 408-16, respectively, of leads 404-1 through 440-16, respectively via ball bonds 406-1 through 406-16 through bond pads (not shown) on integrated circuit 402. Second portions 410-1 through 410-16 extend from first portions 408-1 through 408-16 to outside of encapsulant 440. Thus, the example of FIG. 4 provides sixteen connections to integrated circuit 402. In an example, the method of FIGS. 2A-2K forms packaged integrated circuit 400.

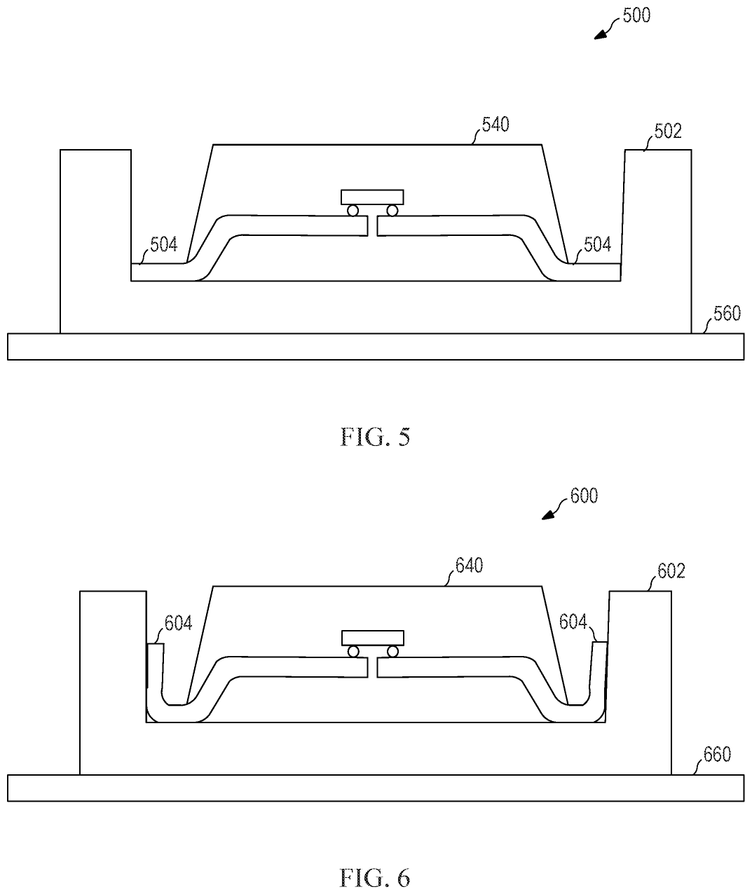

FIG. 5 shows an example of mounting a packaged integrated circuit 500 in an example socket 502, which is mounted on a printed circuit board 560. In this example, packaged integrated circuit 500 is like packaged integrated circuit 100, packaged integrated circuit 300 or packaged integrated circuit 400. In this example, leads 504 extend horizontally and are solder bonded to contacts in the bottom of socket 502. Also, in this example, the bottom surface of leads 504 extend into the bottom surface of encapsulant 540. This allows for greater contact area on leads 504 for a given size package.

FIG. 6 shows another example method of mounting a packaged integrated circuit 600 in socket 602, which is mounted on a printed circuit board 660. In this example, packaged integrated circuit 600 is like packaged integrated circuit 100, packaged integrated circuit 300 or packaged integrated circuit 400. In this example, leads 604 are bent, preferably using a jig, to provide vertical or shoulder contact area with leads in the sides of socket 602. This type of lead contact is more compact and resistant to vibrations, and thus is useful in environments like automotive applications that are subject to such vibrations. Thus, packaged integrated circuit 600 as mounted in socket 602 provides the advantages of shoulder contacts like those provided by quad-flat-no lead (QFN) packages while using a less expensive stamped lead frame like lead frame 218 (FIG. 2A). For this type of mounting, the length of leads 604 is less than the thickness of encapsulant 640 so that the bent leads 604 do not extend above the top surface of packaged integrated circuit 600 and thus create a risk of unwanted contact of lead 604.

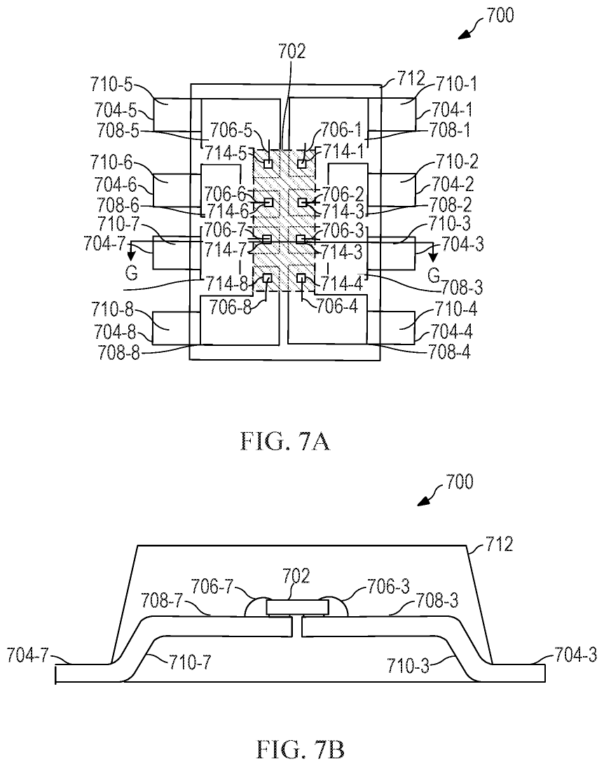

FIG. 7A is a top view diagram of an example packaged integrated circuit 700. In this example, wire bonds 706-1 through 706-8 connect leads 704-1 through 704-8, respectively, to bond pads 714-1 through 714-8, respectively, of integrated circuit 702. Leads 704-1 through 704-8 include first portions 708-1 through 708-8, respectively, and second portions 710-1 through 710-8, respectively. As opposed to the example of FIG. 1, the face of integrated circuit 702 opposite bond pads 714-1 through 714-8 (backside) is mounted to the first portions 708-1 through 708-8 using, for example, heat conductive adhesive. In an example, the backside of integrated circuit 702 may be connected using electrically conductive adhesive to one of leads 704-1 through 704-8 that is designated as a ground lead, for example. In this example, leads 704-1 through 704-8 are formed of aluminum, copper, alloys thereof or other conductive materials. Also, in this example, first portions 708-1 through 708-8 are separated from each other by a spacing of approximately 0.4 mm or less. Encapsulant 712 covers portions of the integrated circuit 702, the first portions 708-1 through 708-8 of leads 704-1 through 704-8 and wire bonds 706-1 through 706-8. In this example, encapsulant 712 is formed of injection molded plastic.

FIG. 7B is a side view of example packaged integrated circuit 700 along cut line AA. Wire bond 706-3 connects lead 704-3 to integrated circuit 702 via bond pads 714-3 (FIG. 7A) on the top surface of integrated circuit 702. In this example, the top surface of integrated circuit 702 is the active surface of integrated circuit 702. In this example, first portions 708-1 through 708-8 are extended above second portions 710-1 through 710-8. In addition, first portions 708-1 through 708-8 are within encapsulant 712. On the other hand, second portions 710-1 through 710-8 extend from first portions 708-1 through 708-8, respectively, such that a portion of a surface of second portions 710-1 through 710-8 is substantially coplanar with a surface of encapsulant 712 and is thus exposed to allow surface bonding of the exposed portions of second portions 710-1 through 710-8 to a circuit board, contacts within a socket or another type of electrical connection. In addition, in this example, the exposed surface of second portions 710-1 through 710-8 extends from within the vertical sides of encapsulant 712 to the end of leads 704-1 through 704-8, respectively, thus providing additional bonding area to the surface of second portions 710-1 through 710-8. In this example, encapsulant 712 has a trapezoidal side profile, but may be any suitable configuration. In an example, packaged integrated circuit 700 is formed using a method like that of FIGS. 2A-2K.

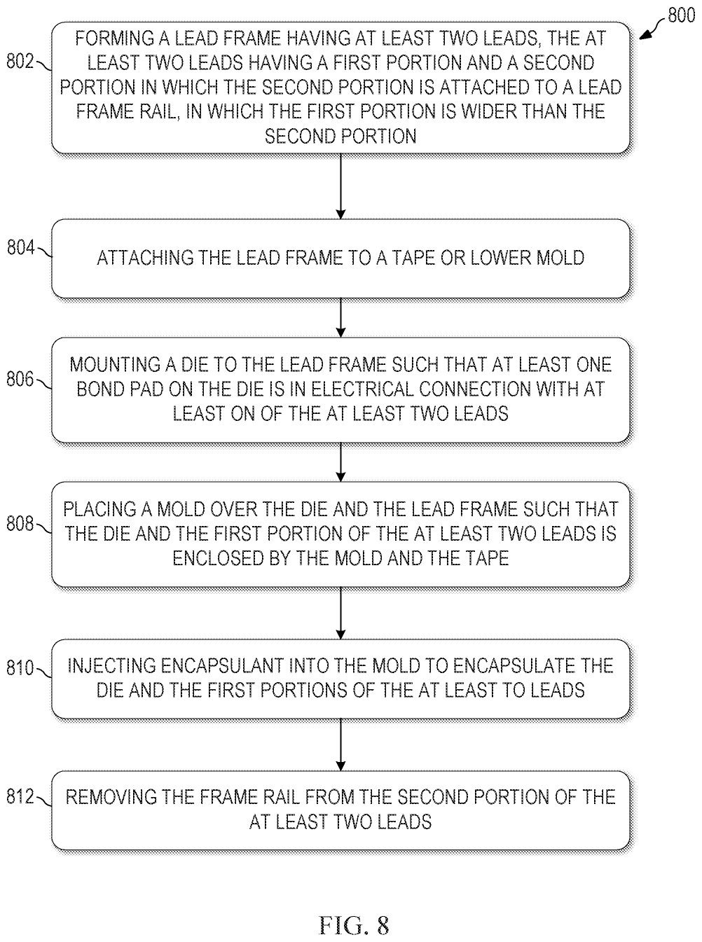

FIG. 8 shows an example method 800 for forming a packaged integrated circuit. Step 802 forms a lead frame such as lead frame 218 (FIG. 2A) having at least two leads, the at least two leads having a first portion and a second portion in which the second portion is attached to a lead frame rail and in which the first portion is wider than the second portion. Step 804 attaches the lead frame to a tape, such as tape 228 (FIG. 2C) or lower mold, such as mold 234 (FIG. 2I). Step 806 mounts a die, such as integrated circuit 202 (FIG. 2E) or integrated circuit 702 (FIG. 7A) to the lead frame such that at least one bond pad on the die is in electrical connection with at least one of the at least two leads. Step 808 places a mold, such as mold 230 (FIG. 2G) over the die and the lead frame such that the die and the first portion of the at least two leads is enclosed by the mold and the tape. Step 810 injects encapsulant into the mold to encapsulate the die and the first portions of the at least to leads with an encapsulant like encapsulant 240 (FIG. 2J). Step 812 removes the frame rail from the second portion of the at least two leads to separate the lead of a package such as packaged integrated circuit 100 (FIG. 1A) from the lead frame.

Modifications are possible in the described examples, and other examples are possible, within the scope of the claims.

What is claimed is:

1. An integrated circuit package comprising:
a die having a first surface, having a second surface opposing the first surface and having at least two bond pads in the first surface;
at least two leads having a first portion and a second portion, the die coupled to the first portion and the at least two bond pads having a conductive connection to at least one of the two leads, the first portion of the at least two leads having a first width greater than a second width of the second portion; and
an encapsulation covering portions of the die and the first portion of the at least two leads, the second portion of the at least two leads extending outside of the encapsulation such that a surface of the second portion is in a plane parallel with a surface of the encapsulation and the second portion extends beyond the encapsulation to a length less than a thickness of the encapsulation.

2. The integrated circuit package of claim 1 in which the surface of the second portion is coplanar with the surface of the encapsulation.

3. The integrated circuit package of claim 1 in which the encapsulation is a molded plastic.

4. The integrated circuit package of claim 1 in which the first surface of the die is an active surface including the bond pads and in which The integrated circuit package further comprises:
at least one ball bond contacting at least one bond pad and one of the two leads.

5. The integrated circuit package of claim 1 in which the first surface of the die is an active surface including the bond pads and in which the second surface of the die is coupled to the at least two leads, The integrated circuit package further comprising:
at least one wire bond conductively connecting at least one of the bond pads to at least one of the at least two leads.

6. The integrated circuit package of claim 1 in which the second portion includes a shoulder configured for contact with a contact in a socket.

7. The integrated circuit package of claim 1 in which the second portions of the at least two leads extend beyond two opposing sides of the encapsulation.

8. The integrated circuit package of claim 1 in which the first portions of the at least two leads is spaced from the surface of the encapsulation.

9. The integrated circuit package of claim 1 in which the first portion of at least one of the two leads includes an extension perpendicular to the direction that the second portion extends from the first portion of the at least one of the two leads and at least one of the bond pads has a conductive connection to the extension.

10. An integrated circuit package comprising:
a die having an active surface including at least two bond pads and having a second surface opposing a first surface;
at least two leads having a first portion and a second portion, the die coupled to the first portion and the at least two bond pads having a ball bond connection to at least one of the two leads, the first portion of the at least two leads having a first width greater than a second width of the second portion; and
an encapsulation covering the die and the first portion of the at least two leads, the second portion of the at least two leads extending outside of the encapsulation such that a surface of the second portion is in a plane in parallel with a surface of the encapsulation and the second portion extends beyond the encapsulation to a length less than a thickness of the encapsulation.

11. The integrated circuit package of claim 10 in which the surface of the second portion is coplanar with the surface of the encapsulation.

12. The integrated circuit package of claim 10 in which the encapsulation is a molded plastic.

13. The integrated circuit package of claim 10 in which the second portion includes a shoulder configured for contact with a contact in a socket.

14. The integrated circuit package of claim 10 in which the second portions of the at least two leads extend beyond two opposing sides of the encapsulation.

15. The integrated circuit package of claim 10 in which the first portions of the at least two leads is spaced from the surface of the encapsulation.

16. A method comprising:
forming a lead frame having at least two leads, the at least two leads having a first portion and a second portion in which the second portion is attached to a lead frame rail, in which the first portion is wider than the second portion;
attaching the lead frame to a tape;
mounting a die to the lead frame such that at least one bond pad on the die is in electrical connection with at least one of the at least two leads;
placing a mold over the die and the lead frame such that the die and the first portion of the at least two leads is enclosed by the mold and the tape;
injecting encapsulant into the mold to cover the die and the first portions of the at least two leads; and
removing the frame rail from the second portion of the at least two leads.

17. The method of claim 16 in which the first portion of the at least two leads is spaced from the tape.

18. The method of claim 16 in which the bond pad is connected to the first portion of at least one of the at least two leads by a ball bond.

19. The method of claim 16 in which the bond pad is connected to the first portion of at least one of the at least two leads by a wire bond.

20. The method of claim 16 in which the encapsulant forms an encapsulation and in which the second portion of the at least two leads is removed from the frame rail by cutting the second portion of the at least two leads such that the second portion of the at least two leads extends beyond the encapsulation by a length less than a thickness of the encapsulation.

21. The method of claim 16 in which the encapsulant is plastic injected into a cavity formed by the mold and the tape.

22. The method of claim 16 in which the lead frame is part of a lead frame strip including a plurality of lead frames and further comprising separating the lead frame from the plurality of lead frames after the injecting encapsulant into the mold.
